(19) United States
(12) Patent Application Publication
(10) Pub. No.: US 2016/0037691 A1
(43) Pub. Date: Feb. 4, 2016

(54) DISCONTINUOUS SHIELDING TAPE FOR DATA COMMUNICATIONS CABLE AND METHOD FOR MAKING THE SAME

(71) Applicant: NEXANS, PARIS (FR)

(72) Inventors: Paul Kroushl, Franklin, MA (US); Paul Vanderlaan, New Holland, PA (US)

(21) Appl. No.: 14/448,017

(22) Filed: Jul. 31, 2014

(51) Int. Cl. H05K 9/00; H01B 11/08

(52) U.S. Cl. CPC H05K 9/0086; H01B 11/08

(57) ABSTRACT

A discontinuous shielding tape includes a first tape layer having a first width and a metallic layer disposed on the first tape layer having a second width. The second width of the metallic layer is narrower than the first width of the first tape layer so as to leave at least two metallic free strips running the longitudinal length of the first tape layer, one on either side of the metal layer. The metallic layer is scored only within the second width of the metal layer with resultant discrete metallic elements such than when the first tape layer is stretched, the discrete metallic elements are separated each by a gap creating the discontinuous shielding tape, where the two metallic free strips are configured to maintain integrity of the first tape layer.

### RELATED APPLICATION

This application is related to pending U.S. patent application Ser. No. 13/779,089.

### BACKGROUND

1. Field of the Invention

This application relates to a shielding tape and method for making the same. More particularly, this application relates to a shielding tape for LAN (Local Area Network) cables and method for the production of such tapes.

2. Description of the Related Art

LAN or network type communication cables are typically constructed from a plurality of twisted pairs (two twisted insulated conductors), enclosed within a jacket. A typical construction includes four twisted pairs inside of a jacket, but many other larger pair count cables are available.

Care is taken to construct these cables in a manner to prevent cross talk with adjacent cables. For example, in a typical installation, many LAN cables may be arranged next to one another, and signals in the pairs from a first cable may cause interference or crosstalk with another pair in an adjacent LAN cable. In order to prevent this, the lay length or twist rate of the pairs in a cable is varied differently from one another. Additionally, when pairs in adjacent cables are running parallel to one another the cross talk can be increased so the pairs within a cable are twisted around one another (helically or SZ stranding) to further decrease interference. Spacing elements can also be used so that the jacket is spaced apart from the pairs so that pairs in adjacent cables are as far away as possible.

Nevertheless, despite all of these features, in some cases, the requirements for increased bandwidth may necessitate additional protection from crosstalk. One such common type of protection is shielding. LAN cable shielding is usually in the form of a foil that is wrapped around the pairs inside the cable, under the jacket. This metal foil is usually wrapped around the assembled core of twisted pairs at or prior to jacketing and is constructed of suitable metals, for example aluminum.

Although the shield is effective for preventing alien crosstalk and other external signal interferences, the shield must be grounded to the connector in order to meet safety regulations. This is a time consuming step that increases the cost to install the shielded cable. One typical example requires a drain wire to be helically coiled around the shield which also increases the overall cable cost.

In the prior art, there have been proposals to mitigate the above effect by providing a discontinuous shielding tape having periodic breaks in the shield. This design makes sure that any signals that travel in the shield do not extend continuously from one end to the other end of the cable, obviating the need for grounding the shield.

However, making such a shielding tape is difficult. For example, one method currently used for manufacturing discontinuous tape is by incising the aluminum side of a polyester film backed aluminum tape. This tape is then stretched to separate the aluminum segments. Care must be taken to cut only the aluminum as the polyester film backing is used to keep the tape contiguous. The polyester film must also be kept thin due to its undesirable fuel loading and potential for smoke generation, However this thinness of the polyester backing tape results in uneven aluminum segment spacing separation and also makes tape breakage common during the manufacturing process,

### OBJECTS AND SUMMARY

The present arrangement overcomes the drawbacks of the prior art by providing a novel construction and manner for making the same for a discontinuous shield tape, for use for example in LAN cables or other such implementations.

To this end, in accordance with one embodiment, the present arrangement provides for a discontinuous foil shield having a first tape layer having a first width and a metallic layer disposed on the first tape layer having a second width. The second width of the metallic layer is narrower than the first width of the first tape layer so as to leave at least two metallic free strips running the longitudinal length of the first tape layer, one on either side of the metal layer.

The metallic layer is scored only within the second width of the metal layer with resultant discrete metallic elements such than when the first tape layer is stretched, the discrete metallic elements are separated each by a gap creating the discontinuous shielding tape, where the two metallic free strips, running the longitudinal length of the tape, are configured to maintain integrity of the first tape layer.

In accordance with another embodiment, the present arrangement provides a discontinuous shielding tape Includes a first tape layer having a first width and a metallic layer disposed on the first tape layer has a second width, where the second width of the metallic layer is narrower than the first width of the first tape layer so as to leave at least two metallic free strips running the longitudinal length of the first tape layer, one on either side of the metal layer.

The metallic layer and the first tape layer are periodically punched completely through only within the second width of the metal layer with resultant discrete metallic elements and corresponding tape layer, such that the discrete metallic elements are separated each by a full air gap created between the discrete metallic elements, where the two metallic free strips are configured to maintain integrity and continuity of the first tape layer.

### BRIEF DESCRIPTION OF THE DRAWINGS:

The present invention can be best understood through the following description and accompanying drawings, wherein:

FIG. 1 shows a shielding tape substrate with a metal layer thereon, in accordance with one embodiment;

FIG. 2 shows a shielding tape substrate with a scored metal layer thereon, in accordance with one embodiment;

FIG. 3A shows a shielding tape substrate with a metal layer thereon having discrete discontinuous metal segments, in accordance with one embodiment;

FIG. 3B shows a shielding tape substrate with a metal layer thereon having discrete discontinuous metal segments, in accordance with another embodiment;

FIG. 4 shows a shielding tape substrate with a metal layer thereon having discrete discontinuous metal segments and upper tape layer, in accordance with one embodiment; and

FIG. 5 shows a shielding tape substrate with a metal layer thereon having discontinuous metal segments, in accordance with another embodiment.

### DETAILED DESCRIPTION

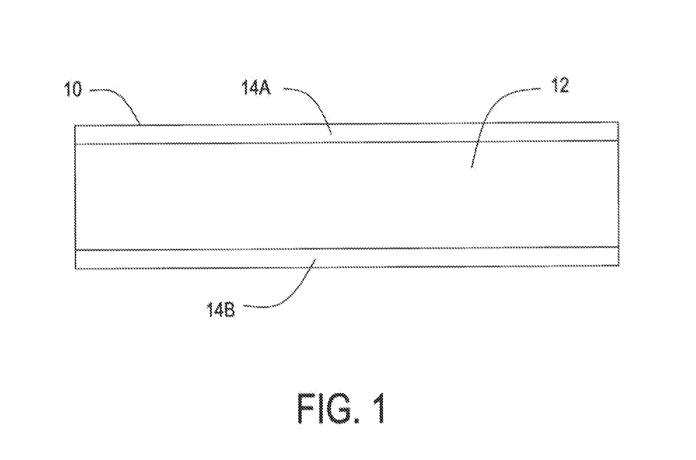

In one embodiment of the present arrangement as shown in FIG. 1, a first polyester substrate tape 10 is provided having a laminated metallic surface 12 thereon. Tape 10 is preferably made from polyester but it may be made from other polymers. Metal layer 12 is preferably made from an aluminum deposit but other metals may be used. In one preferred arrangement, tape 10 is approximately 0.003″ thick and approximately 1.0″-1.5″ wide. The associated metal layer 12 deposited thereon is an aluminum layer approximately 0.001″-0.002″ thick and approximately 0.25″ narrower than the width of tape 10, Such a size would be typically applied to a common LAN type cable having four twisted pairs. However, it is understood that the dimensions are only considered exemplary and other thicknesses and widths for tape 10 and metal layer 12 are within the contemplation of the present invention, depending on the desired final structure of the cable n which it will be used.

As shown in FIG. 1, tape 10 is constructed having a width that is wider than the metallic layer 12 such that tape 10 has two metallic free segments 14a and 14b on each side of metallic layer 12 running the length of tape 10. According to the above exemplary dimensions, each such metallic free segment 14a and 14b is approximately 0.125″ wide on either side of metallic layer 12, running the entire length of tape 10.

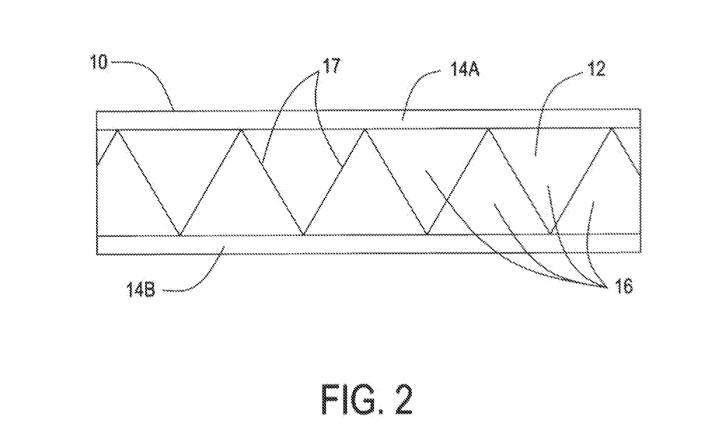

As shown in FIG. 2, in order to make metallic layer 12 discontinuous, metallic layer 12 is scored by means of a punch or scribing blade that incises across the entirety of the width of metallic layer 12 forming score lines 17. As a result, metallic layer 12 is now formed by a series of discretely scored metallic elements 16, which at this stage have a de minims separation as score lines 17 are at this stage very narrow. Each metallic element 16 is in the form of a triangle, with alternating orientation along the length of tape 10. However, it is to be understood that metallic elements 16 may have other shapes such as rectangles, squares etc . . . as desired. In one example, the longitudinal width along tape 10 of each metallic segment 16 is between 1.0″-6.0″ (for triangles measured from mid-height) however, the invention is equally applicable to any length metallic segments 16.

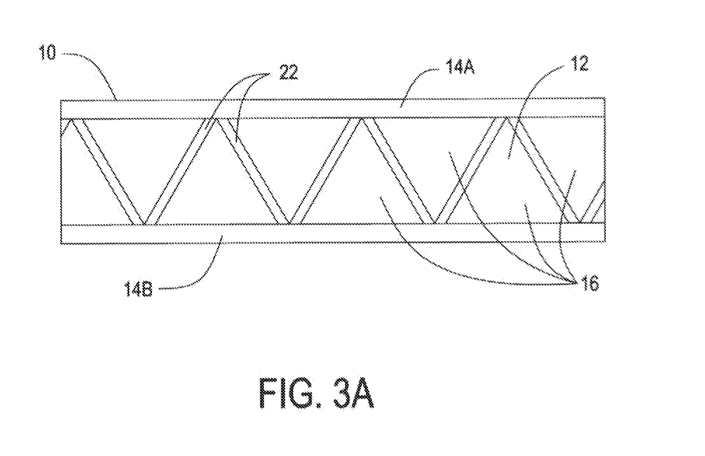

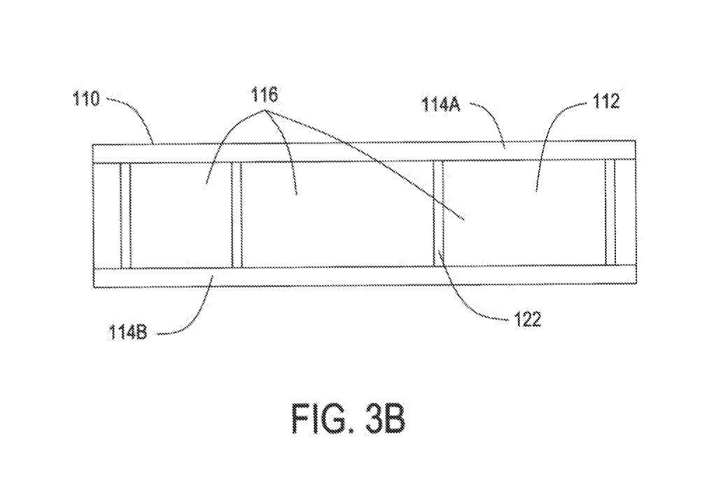

As shown in FIG. 3A, polyester tape 10 is stretched slightly separating metallic elements 16 of metallic layer 12 so as to make metallic layer 12 discontinuous. The amount of stretching of tape 10 is preferably done so as to create gaps 22 of approximately 0.05″ and 0.125″ depending on the desired final structure.

The metallic free edges 14a and 14b provide structural integrity to tape 10 during the scoring process, shown in FIG. 2. For example during scoring of the metallic layer 12 into elements 16 it is possible that the blade or scoring mechanism may damage tape 10. However, because of metallic free edges 14a and 14b, the scoring process does not need to traverse the entire width of tape 10 in order to complete score across metallic layer 12 to create discrete metallic elements 16. As such, if any incidental scoring of tape 10 occurs during scoring of metallic layer 12, then during stretching, tape 10 will at least have partially un-scored areas in the region of metallic free zones 14a and 14b to maintain tape integrity throughout the stretch.

Another advantage of metallic free zones 14a and 14b is that they can help prevent the unintentional shorting of adjacent metallic segments 16 when the tape is applied around the cable core. For example, if discontinuous metallic segments extended all the way to the edge of a tape, when that tape is applied to a cable core at an angle (spiral wrapped as with typical shielding tape), there is the possibility that the edges of such metal segments may intermittently touch, despite being longitudinally discontinuous, creating electrical continuity due to tape edge curling or deformation during manufacturing or later installation. In the current design with foil free edges 14a and 14b, even after tape 10 is applied to a cable core at an angle, the discontinuous metallic elements 16 do not touch and thus do not accidentally create a continuous conducting situation.

As an alternative embodiment, FIG. 33 is the same as FIG. 3A only it shows a tape 100, with metallic layer 112 and metal free edges 114A and 114B. In this embodiment, metallic elements 116 of metallic layer 112 are in the shape of squares or rectangles as opposed to triangles, but otherwise of substantially the same dimensions.

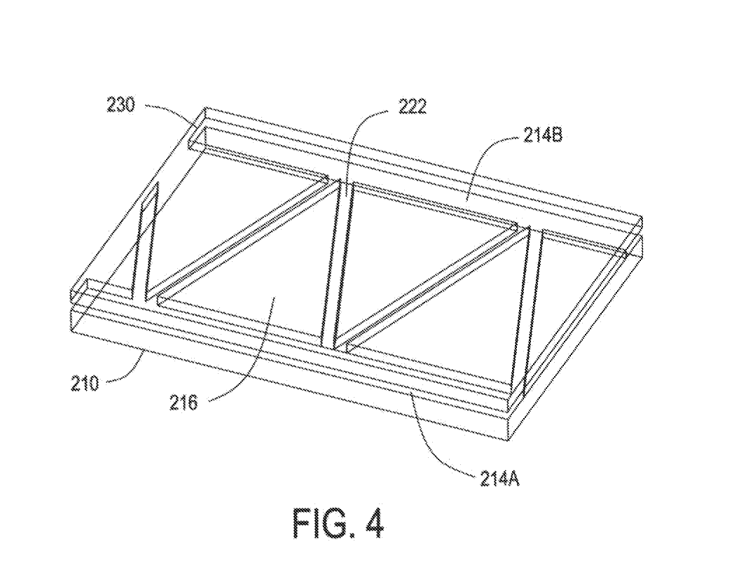

In another embodiment, as shown in FIG. 4, a tape 200 is provided again with metallic layer 212 and metal free edges 214A and 2143. In this embodiment, after tape 210 is stretched to form independent metallic elements 212 as shown above in FIG. 3, and optional second tape layer 230 is applied over metallic elements 216 for additional stability. This second tape layer 230 may be made of polyester and is substantially 0.0005″ and 0.001″ but it is not limited in these respects.

This second tape layer 230 also provides strength to the design to prevent breakage during later cable manufacturing processes. As noted above, accidental scoring of tape 210 during scoring of metallic layer 212 can lead to breakage or at least a generally weakened tape 210 that could break when being applied during cable assembly. The addition of upper tape layer 230 adds a layer of stability to the overall design.

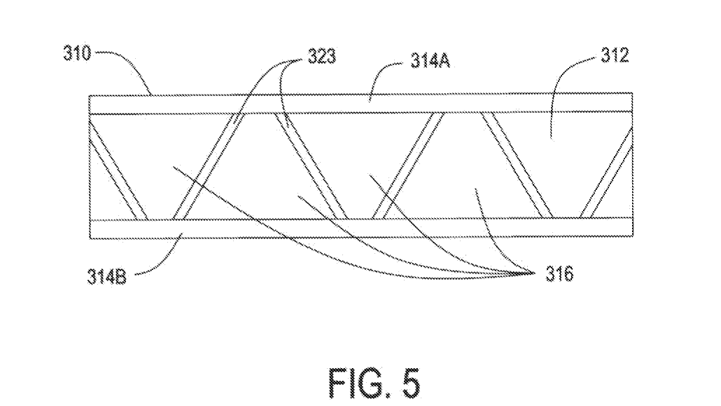

In another embodiment shown in FIG. 5, a tape 300 is provided again with metallic layer 312 and metal free edges 314A and 314B, In this embodiment, rather than creating gaps 22 through scoring and stretching as described above with FIGS. 2 and 3A/3B, segments 316 are formed in metallic layer 312 on tape 310, by completely punching through metal layer 312 and tape 310 (no stretching) forming segments 316 with complete aft gaps 323 there between. Such an arrangement still retains metallic free edges 314a and 314b and the advantages appurtenant thereto. Moreover, in this arrangement, the metallic segments 316 and the underlying tape 310 (that was not punched out) act as rungs in a ladder like arrangement with the longitudinally running metal free edges 314a and 314b acting as the ladder rails. Such an arrangement may in some cases have an advantage that complete punching of tape 310 may be accomplished with less variation as opposed to the prior scoring and stretching method from FIGS. 2 and 3A/3B depending on the various thicknesses dimensions and materials being used.

While only certain features of the invention have been illustrated and described herein, many modifications, substitutions, changes or equivalents will now occur to those skilled in the art. It is therefore, to be understood that this application is intended to cover all such modifications and changes that fall within the true spirit of the invention.

What is claimed is:

1. A discontinuous shielding tape comprising:
a first tape layer having a first width; and
a metallic layer disposed on said first tape layer having a second width,
wherein said second width of said metallic layer is narrower than said first width of said first tape layer so as to leave at least two metallic free strips running the longitudinal length of said first tape layer, one on either side of said metal layer,
wherein said metallic layer is scored only within said second width of said metal layer with resultant discrete metallic elements such than when said first tape layer is stretched, said discrete metallic elements are separated each by a gap creating said discontinuous shielding tape, where said two metallic free strips are configured to maintain integrity of said first tape layer.

2. The discontinuous shielding tape as claimed in claim 1 wherein said first tape layer is made of polyester.

3. The discontinuous shielding tape as claimed in claim 1, wherein said first tape layer is substantially 0.003″ in thickness.

4. The discontinuous shielding tape as claimed in claim 1, wherein said first tape layer is substantially 1.0″-1.5″ in width.

5. The discontinuous shielding tape as claimed in claim 1, wherein said metallic layer is substantially 0.001″-0.002″ in thickness.

6. The discontinuous shielding tape as claimed in claim 1, wherein said metallic layer is substantially 0.25″ in width less than the width of said first tape layer.

7. The discontinuous shielding tape as claimed in claim 6, wherein said metallic free strips on either side of said metallic layer are each substantially 0.125″ in width.

8. The discontinuous shielding tape as claimed in claim 1, wherein said discrete metallic elements are each separated by a gap that is substantial between 0.05″-0.125″.

9. The discontinuous shielding tape as claimed in claim 1, further comprising a second tape layer disposed over said metal layer.

10. The discontinuous shielding tape as claimed in claim 9, wherein said second tape layer is made of polyester.

11. The discontinuous shielding tape as claimed in claim 9, wherein said second tape layer is substantially between 0.0005″-0.001″ in thickness.

12. The discontinuous shielding tape as claimed in claim 9, wherein said second tape layer is applied after said first tape layer is stretched to form said discrete metallic elements.

13. A discontinuous shielding tape comprising:
a first tape layer having a first width; and
a metallic layer disposed on said first tape layer having a second width,
wherein said second width of said metallic layer is narrower than said first width of said first tape layer so as to leave at least two metallic free strips running the longitudinal length of said first tape layer, one on either side of said metal layer,
wherein said metallic layer and said first tape layer are periodically punched completely through only within said second width of said metal layer with resultant discrete metallic elements and corresponding tape layer, such that said discrete metallic elements are separated each by a full air gap created between said discrete metallic elements, where said two metallic free strips are configured to maintain integrity and continuity of said first tape layer.
